(19) United States
(12) Patent Application Publication
(10) Pub. No.: US 2023/0318252 A1
(43) Pub. Date: Oct. 5, 2023

(54) CONTROL METHOD OF LASER SYSTEM, LASER SYSTEM, AND ELECTRONIC DEVICE MANUFACTURING METHOD

(71) Applicant: Gigaphoton Inc., Tochigi (JP)

(72) Inventor: Takeshi ASAYAMA, Oyama-shi (JP)

(73) Assignee: Gigaphoton Inc., Tochigi (JP)

(21) Appl. No.: 18/332,597

(22) Filed: Jun. 9, 2023

Related U.S. Application Data
(63) Continuation of application No. PCT/JP2021/002095, filed on Jan. 21, 2021.

(51) Int. Cl. H01S 3/134; H01S 3/23; H01S 3/13; G03F 7/20

(52) U.S. Cl. CPC H01S 3/134; H01S 3/2308; H01S 3/1305; G03F 7/70025; H01S 3/225

(57) ABSTRACT

A laser system includes an oscillation stage laser configured to output first laser light, and an amplification stage laser configured to amplify the first laser light and output second laser light. A control method of the laser system includes determining a condition under which an amplification characteristic of the amplification stage laser changes, acquiring relationship between pulse energy of the first laser light and a parameter of the second laser light when the condition is determined to be satisfied, and setting target pulse energy of the first laser light based on the relationship.

### CROSS-REFERENCE TO RELATED APPLICATIONS

The present application claims the benefit of International Application No. PCT/JP2021/002095, filed on Jan. 21, 2021 the entire contents of which are hereby incorporated by reference.

### BACKGROUND

### 1. Technical Field

The present disclosure relates to a control method of a laser system, a laser system, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2006/239309
Patent Document 2: Japanese Patent Application Publication No. 2006-080279
Patent Document 3: US Patent Application Publication No. 2018/123312
Patent Document 4: US Patent Application Publication No. 2019/280451

### SUMMARY

A control method of a laser system, according to an aspect of the present disclosure, which includes an oscillation stage laser configured to output first laser light, and an amplification stage laser configured to amplify the first laser light and output second laser light, includes determining a condition under which an amplification characteristic of the amplification stage laser changes; acquiring relationship between pulse energy of the first laser light and a parameter of the second laser light when the condition is determined to be satisfied; and setting target pulse energy of the first laser light based on the relationship.

A laser system according to an aspect of the present disclosure includes an oscillation stage laser configured to output first laser light; an amplification stage laser configured to amplify the first laser light and output second laser light; and a processor configured to determine a condition under which an amplification characteristic of the amplification stage laser changes, acquire relationship between pulse energy of the first laser light and a parameter of the second laser light when the condition is determined to be satisfied, and set target pulse energy of the first laser light based on the relationship.

An electronic device manufacturing method according to an aspect of the present disclosure includes generating laser light using a laser system, outputting the laser light to an exposure apparatus, and exposing a photosensitive substrate to the laser light in the exposure apparatus to manufacture an electronic device. Here, the laser system includes an oscillation stage laser configured to output first laser light; an amplification stage laser configured to amplify the first laser light and output second laser light; and a processor configured to determine a condition under which an amplification characteristic of the amplification stage laser changes, acquire relationship between pulse energy of the first laser light and a parameter of the second laser light when the condition is determined to be satisfied, and set target pulse energy of the first laser light based on the relationship.

### BRIEF DESCRIPTION OF THE DRAWINGS

Embodiments of the present disclosure will be described below merely as examples with reference to the accompanying drawings.

FIG. 1 schematically shows the configuration of a laser system according to a comparative example.

FIG. 2 is a flowchart showing an operation procedure from installation to the end of the lifetime of a chamber module in the comparative example.

FIG. 3 schematically shows the configuration of the laser system according to a first embodiment.

FIG. 4 is a flowchart showing an operation procedure from installation to the end of the lifetime of the chamber module in the first embodiment.

FIG. 5 is a flowchart for explaining details of a setting process of MO target pulse energy in the first embodiment.

FIG. 6 is a graph showing the measurement result of the relationship between pulse energy of first laser light and pulse energy of second laser light.

FIG. 7 is a graph showing the relationship between the pulse energy of the first laser light and a change rate of the pulse energy of the second laser light.

FIG. 8 is a flowchart for explaining details of the setting process of the MO target pulse energy in a second embodiment.

FIG. 9 is a graph showing the measurement result of the relationship between the pulse energy of the first laser light and the pulse energy variation of the second laser light.

FIG. 10 is a graph showing the relationship between the pulse energy of the first laser light and the absolute value of the change rate of the pulse energy variation of the second laser light.

FIG. 11 schematically shows the configuration of the laser system according to a third embodiment.

FIG. 12 is a flowchart for explaining details of the setting process of the MO target pulse energy in the third embodiment.

FIG. 13 shows an example of interference fringes due to the second laser light measured by an interferometer.

FIG. 14 is a graph showing the relationship between the pulse energy of the first laser light and contrast of the interference fringes.

FIG. 15 schematically shows an optical path between a master oscillator and a power oscillator in the laser system according to a fourth embodiment.

FIG. 16 schematically shows the optical path between the master oscillator and the power oscillator in the laser system according to the fourth embodiment.

FIG. 17 schematically shows the optical path between the master oscillator and the power oscillator in the laser system according to the fourth embodiment.

FIG. 18 schematically shows the configuration of the laser system according to a fifth embodiment.

FIG. 19 shows the power oscillator shown in FIG. 18 as viewed from a direction different from that of FIG. 18.

FIG. 20 schematically shows the configuration of an exposure apparatus connected to the laser system.

### DESCRIPTION OF EMBODIMENTS

<Content>
1. Comparative example
   1.1 Configuration
      1.1.1 Master oscillator MO
      1.1.2 MO energy monitor 16 and high reflection mirrors 31, 32
      1.1.3 Power oscillator PO
      1.1.4 PO energy monitor 17 and shutter 18
      1.1.5 Laser control processor 30
   1.2 Operation
      1.2.1 Laser control processor 30
      1.2.2 Master oscillator MO
      1.2.3 MO energy monitor 16 and high reflection mirrors 31, 32
      1.2.4 Power oscillator PO
      1.2.5 PO energy monitor 17 and shutter 18
      1.2.6 Voltage control
      1.2.7 Gas pressure control
      1.2.8 Setting of MO target pulse energy
   1.3 Problem of comparative example
2. Laser system 1a to set MO target pulse energy as measuring pulse energy Epo of second laser light B2
   2.1 Configuration
   2.2 Operation
   2.3 Setting process of MO target pulse energy
   2.4 Effect
3. Laser system 1a setting MO target pulse energy as measuring pulse energy variation σepo of the second laser light B2
   3.1 Operation
   3.2 Effect
4. Laser system 1c setting MO target pulse energy as measuring contrast C of interference fringes due to second laser light B2
   4.1 Configuration
   4.2 Operation
   4.3 Other configuration example
   4.4 Effect
5. Laser system 1d in which MO energy monitor 16 also receives light other than light output from master oscillator MO
   5.1 Configuration and operation
   5.2 Effect
6. Laser system 1e including ring resonator
   6.1 Configuration
   6.2 Operation
   6.3 Effect
7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Comparative Example

### 1.1 Configuration

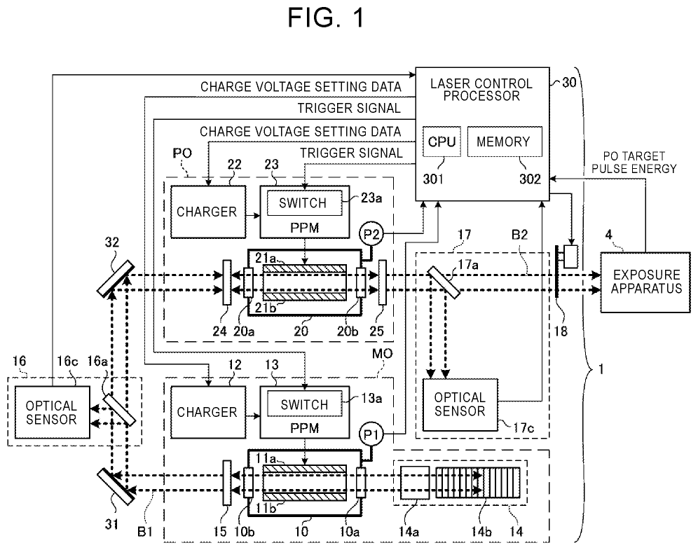

FIG. 1 schematically shows the configuration of a laser system 1 according to a comparative example. The laser system 1 includes a master oscillator MO, a power oscillator PO, an MO energy monitor 16, a PO energy monitor 17, a shutter 18, a laser control processor 30, and high reflection mirrors 31, 32. The laser system 1 is connected to an exposure apparatus 4.

1.1.1 Master Oscillator MO

The master oscillator MO includes a laser chamber 10, a pair of discharge electrodes 11a, 11b, a charger 12, a pulse power module (PPM) 13, a line narrowing module 14, an output coupling mirror 15, and a pressure sensor P1. The line narrowing module 14 and the output coupling mirror 15 configure an optical resonator. The laser chamber 10 is arranged on the optical path of the optical resonator. The master oscillator MO is a discharge-excitation-type gas laser device and corresponds to the oscillation stage laser in the present disclosure.

The laser chamber 10 is filled with a laser gas containing, for example, an argon gas or a krypton gas as a rare gas, fluorine gas as a halogen gas, a neon gas as a buffer gas, and the like. Windows 10a, 10b are arranged at both ends of the laser chamber 10.

The charger 12 holds electric energy to be supplied to the pulse power module 13. The pulse power module 13 includes a charging capacitor (not shown) and a switch 13a. The charger 12 is connected to the charging capacitor of the pulse power module 13. The charging capacitor of the pulse power module 13 is connected to the discharge electrode 11a. The discharge electrode 11b is connected to a ground potential.

The line narrowing module 14 includes a prism 14a and a grating 14b. Instead of the line narrowing module 14, a high reflection mirror may be used. The output coupling mirror 15 is made of a material that transmits light having a wavelength selected by the line narrowing module 14, and one surface thereof is coated with a partial reflection film. The output coupling mirror 15 corresponds to the second partial reflection mirror in the present disclosure. The pressure sensor P1 is attached to the laser chamber 10.

1.1.2 MO Energy Monitor 16 and High Reflection Mirrors 31, 32

The MO energy monitor 16 and the high reflection mirrors 31, 32 are arranged on the optical path of first laser light B1 being pulse laser light output from the master oscillator MO. The MO energy monitor 16 corresponds to the energy monitor in the present disclosure.

The MO energy monitor 16 includes a beam splitter 16a located on the optical path of the first laser light B1 and an optical sensor 16c located on the optical path of the light reflected by the beam splitter 16a. A light concentrating optical system (not shown) may be arranged between the beam splitter 16a and the optical sensor 16c. The optical sensor 16c is configured to output an electric signal corresponding to pulse energy Emo of the first laser light B1 entering the MO energy monitor 16.

The MO energy monitor 16 is not limited to being arranged between the high reflection mirrors 31, 32. The MO energy monitor 16 may be arranged between the master oscillator MO and the high reflection mirror 31, or may be arranged between the high reflection mirror 32 and the power oscillator PO.

Each of the high reflection mirrors 31, 32 is configured such that the position and orientation thereof can be changed by an actuator (not shown). The high reflection mirrors 31, 32 configure a beam steering unit for adjusting an incident position and an incident direction of the first laser light B1 on the power oscillator PO.

1.1.3 Power Oscillator PO

The power oscillator PO is arranged on the optical path of the first laser light B1 that has passed through the MO energy monitor 16 and the beam steering unit.

The power oscillator PO includes a laser chamber 20, a pair of discharge electrodes 21a, 21b, a charger 22, a pulse power module 23, a rear mirror 24, an output coupling mirror 25, and a pressure sensor P2. The laser chamber 20 is provided with two windows 20a, 20b. The power oscillator PO is a discharge-excitation-type gas laser device, and corresponds to the amplification stage laser in the present disclosure.

The rear mirror 24 is made of a material that transmits the first laser light B1, and one surface thereof is coated with a partial reflection film. The rear mirror 24 corresponds to the first partial reflection mirror in the present disclosure. The reflectance of the rear mirror 24 is set higher than the reflectance of the output coupling mirror 25. The rear mirror 24 and the output coupling mirror 25 configure a Fabry-Perot type optical resonator. The pulse power module 23 includes a switch 23a.

In other respects, the above-described components of the power oscillator PO are similar to the corresponding components of the master oscillator MO.

1.1.4 PO Energy Monitor 17 and Shutter 18

The PO energy monitor 17 is arranged on the optical path of the second laser light B2 being pulse laser light output from the power oscillator PO. The PO energy monitor 17 includes a beam splitter 17a and an optical sensor 17c. These components are similar to the corresponding components of the MO energy monitor 16.

The shutter 18 is arranged on the optical path of the second laser light B2 that has passed through the PO energy monitor 17. The shutter 18 is configured to be switchable between a first state of allowing the second laser light B2 to pass therethrough toward the exposure apparatus 4 and a second state of blocking the second laser light B2 to stop output thereof to the exposure apparatus 4.

1.1.5 Laser Control Processor 30

The laser control processor 30 is a processing device including a memory 302 in which a control program is stored and a CPU 301 which executes the control program. The laser control processor 30 is specifically configured or programmed to perform various processes included in the present disclosure. The laser control processor 30 corresponds to the processor in the present disclosure.

### 1.2 Operation

1.2.1 Laser Control Processor 30

The laser control processor 30 sets target pulse energy of the first laser light B1. Hereinafter, the target pulse energy of the first laser light B1 is referred to as MO target pulse energy.

The laser control processor 30 further receives setting data of the target pulse energy of the second laser light B2 from the exposure apparatus 4. Hereinafter, the target pulse energy received from the exposure apparatus 4 is referred to as PO target pulse energy.

The laser control processor 30 transmits setting data of the charge voltages to the chargers 12, 22, respectively, based on the MO target pulse energy and the PO target pulse energy. The laser control processor 30 also transmits trigger signals to the pulse power modules 13, 23.

1.2.2 Master Oscillator MO

When the pulse power module 13 receives the trigger signal from the laser control processor 30, the pulse power module 13 generates a pulse high voltage from the electric energy charged in the charger 12 and applies the high voltage between the discharge electrodes 11a, 11b.

When the high voltage is applied between the discharge electrodes 11a, 11b, discharge occurs between the discharge electrodes 11a, 11b. The laser medium in the laser chamber 10 is excited by the energy of the discharge and shifts to a high energy level. When the excited laser medium then shifts to a low energy level, light having a wavelength corresponding to the difference between the energy levels is emitted.

The light generated in the laser chamber 10 is output to the outside of the laser chamber 10 through the windows 10a, 10b. The beam width of the light output through the window 10a of the laser chamber 10 is expanded by the prism 14a, and then the light is incident on the grating 14b. The light incident on the grating 14b from the prism 14a is reflected by a plurality of grooves of the grating 14b and is diffracted in a direction corresponding to a wavelength of the light.

The prism 14a reduces the beam width of the diffracted light from the grating 14b and returns the light to the laser chamber 10 through the window 10a. The output coupling mirror 15 transmits and outputs a part of the light output from the window 10b of the laser chamber 10, and reflects the other part back into the laser chamber 10.

In this way, the light output from the laser chamber 10 reciprocates between the line narrowing module 14 and the output coupling mirror 15, and is amplified each time the light passes through the discharge space between the discharge electrodes 11a, 11b. The light is line-narrowed each time being turned back in the line narrowing module 14. Thus, the light having undergone laser oscillation and line narrowing is output as the first laser light B1 from the output coupling mirror 15.

1.2.3 MO Energy Monitor 16 and High Reflection Mirrors 31, 32

The MO energy monitor 16 detects the pulse energy Emo of the first laser light B1 and outputs the detection result to the laser control processor 30. The high reflection mirrors 31, 32 guide the first laser light B1 to the rear mirror 24 of the power oscillator PO.

1.2.4 Power Oscillator PO

When the pulse power module 23 receives the trigger signal from the laser control processor 30, the pulse power module 23 generates a pulse high voltage from the electric energy charged in the charger 22 and applies the high voltage between the discharge electrodes 21a, 21b. The delay time of the trigger signal to the pulse power module 23 with respect to the trigger signal to the pulse power module 13 is set so that the timing at which the discharge occurs between the discharge electrodes 21a, 21b and the timing at which the first laser light B1 enters the laser chamber 20 via the rear mirror 24 and the window 20a are synchronized with each other.

The first laser light B1 reciprocates between the rear mirror 24 and the output coupling mirror 25, and is amplified each time it passes through the discharge space between the discharge electrodes 21a, 21b. The amplified light is output from the output coupling mirror 25 as the second laser light B2.

1.2.5 PO Energy Monitor 17 and Shutter 18

The PO energy monitor 17 detects pulse energy Epo of the second laser light B2 and outputs the detection result to the laser control processor 30. When the second laser light B2 is output to the exposure apparatus 4, the shutter 18 is controlled to be in the first state of causing the second laser light B2 to pass through the shutter 18. When the output to the exposure apparatus 4 is stopped in the initial adjustment of the laser system 1 or the like, the shutter 18 is controlled to be in the second state of blocking the second laser light B2.

1.2.6 Voltage Control

The laser control processor 30 performs feedback control of the charge voltage of the charger 12 based on the MO target pulse energy and the pulse energy Emo of the first laser light B1 received from the MO energy monitor 16. The laser control processor 30 performs feedback control of the charge voltage of the charger 22 based on the PO target pulse energy and the pulse energy Epo of the second laser light B2 received from the PO energy monitor 17.

While the laser oscillation by the master oscillator MO and the power oscillator PO is repeated, the discharge electrodes 11a, 11b, 21a, 22b and other optical elements may deteriorate. Then, the charge voltage required for controlling the pulse energy Emo of the first laser light B1 and the pulse energy Epo of the second laser light B2 to be close to the respective target values gradually increases.

1.2.7 Gas Pressure Control

In the master oscillator MO, when the charge voltage of the charger 12 exceeds a threshold value, the laser control processor 30 controls the gas supply device (not shown) to inject the laser gas into the laser chamber 10 to increase the gas pressure in the laser chamber 10. By increasing the gas pressure, the charge voltage required for controlling the pulse energy Emo of the first laser light B1 to be close to the target value can be reduced.

As the laser oscillation by the master oscillator MO is further repeated, the charge voltage required for controlling the pulse energy Emo of the first laser light B1 to be close to the target value may increase again. When the charge voltage of the charger 12 exceeds the threshold value, the laser control processor 30 injects the laser gas again into the laser chamber 10 to further increase the gas pressure in the laser chamber 10. Therefore, as the laser oscillation by the master oscillator MO is performed for a long time, the gas pressure in the laser chamber 10 gradually increases.

Similarly, in the power oscillator PO as well, the gas pressure in the laser chamber 20 gradually increases.

The pressure sensors P1, P2 detect the gas pressure in the laser chambers 10, 20, and transmit the detection results to the laser control processor 30, respectively. When the gas pressure in the laser chamber 10 exceeds the upper limit value, the chamber module of the master oscillator MO may need to be replaced. When the gas pressure in the laser chamber 20 exceeds the upper limit value, the chamber module of the power oscillator PO may need to be replaced.

1.2.8 Setting of MO Target Pulse Energy

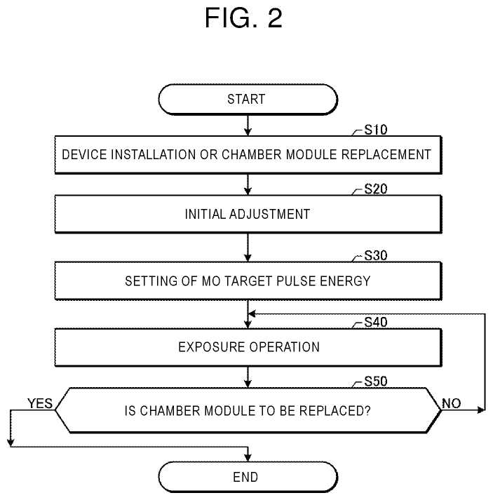

FIG. 2 is a flowchart showing an operation procedure from installation to the end of the lifetime of a chamber module in the comparative example.

In S10, a device is installed or a chamber module is replaced. Here, the device is the master oscillator MO or the power oscillator PO. The chamber module is a chamber module of the master oscillator MO or the power oscillator PO. The chamber module of the master oscillator MO is a module including the laser chamber 10 and the discharge electrodes 11a, 11b. The chamber module of the power oscillator PO is a module including the laser chamber 20 and the discharge electrodes 21a, 21b. Thus, a new chamber module is installed.

In S20, the initial adjustment is performed. The initial adjustment includes alignment of the optical elements, adjustment of the laser gas to be filled in the laser chamber 10 or 20, and the like. In the initial adjustment, the laser control processor 30 controls the shutter 18 to be in the second state to block the second laser light B2.

In S30, the laser control processor 30 sets the MO target pulse energy. The MO target pulse energy set here is fixed to the same value until the operation procedure of the present flowchart ends.

In S40, the laser control processor 30 controls the laser system 1 to perform laser oscillation for outputting the second laser light B2 to the exposure apparatus 4. The laser control processor 30 controls the shutter 18 to be in the first state to allow the second laser light B2 to pass toward the exposure apparatus 4. Further, the laser control processor 30 controls the charge voltages of the chargers 12, 22 to control the pulse energy Emo of the first laser light B1 and the pulse energy Epo of the second laser light B2.

After the exposure operation is started, the laser control processor 30 performs determination of S50 at regular intervals. The determination of S50 is a determination of whether or not to replace the chamber module.

The laser control processor 30 determines to replace the chamber module, for example, when any of the following criteria (1) to (4) is satisfied.
(1) The number of oscillation pulses after installation of the device or replacement of the chamber module in S10 has reached a first number of pulses Sm.
(2) The elapse time after installation of the device or replacement of the chamber module in S10 has reached a first elapse time Tm.
(3) The gas pressure in the laser chamber 10 or 20 exceeds the upper limit value.
(4) The high voltage to be applied between the discharge electrodes 11a, 11b or between the discharge electrodes 21a, 21b exceeds the upper limit value.

Here, the first number of pulses Sm is set to be, for example, in a range of 30×10⁹ pulses or more and 50×10⁹ pulses or less. The first elapse time Tm is set to be, for example, in a range of 1 year or more and 2 years or less. The upper limit value of the gas pressure is set to be, for example, in a range of 350 kPa or more and 420 kPa or less. The upper limit value of the high voltage is set to be, for example, in a range of 25 kV or more and 28 kV or less. Whether or not the high voltage exceeds the upper limit value may be determined based on the charge voltage of the charger 12 or 22. When only one of the master oscillator MO and the power oscillator PO satisfies any of the criteria (1) to (4) described above, only the one chamber module may be replaced, or both chamber modules may be replaced.

When determining not to replace the chamber module (S50: NO), the laser control processor 30 returns to S40 and continues the exposure operation. When determining to replace the chamber module (S50: YES), the laser control processor 30 ends the operation of the present flowchart.

### 1.3 Problem of Comparative Example

The pulse energy Emo of the first laser light B1 is preferably high from the viewpoint of obtaining desirable characteristics of the second laser light B2, but is preferably low from the viewpoint of extending the lifetime of the laser chambers 10, 20. In the comparative example, the MO target pulse energy is fixed to the value set in S30 described above, but in this case, there are the following problems (1) to (3).
(1) The optimum value of the MO target pulse energy may differ depending on the PO target pulse energy. For example, when the MO target pulse energy is set to the optimum value in the case that the PO target pulse energy is 10 mJ and the PO target pulse energy is changed to 15 mJ, the pulse energy Emo of the first laser light B1 becomes lower than the optimum value in the case that the PO target pulse energy is 15 mJ. Therefore, there is a possibility that the characteristics of the second laser light B2 become worse than expected. Further, when the MO target pulse energy is set to the optimum value in the case that the PO target pulse energy is 15 mJ and the PO target pulse energy is changed to 10 mJ, the pulse energy Emo of the first laser light B1 becomes higher than the optimum value in the case that the PO target pulse energy is 10 mJ. Therefore, there is a possibility that the lifetime of the laser chamber 10 becomes shorter than expected.
(2) When the laser chamber 20 and the optical elements in the subsequent stages deteriorate, the oscillation condition of the power oscillator PO may change, and the optimum value of MO target pulse energy may increase. In this case, the pulse energy Emo of the first laser light B1 becomes lower than the optimum value. Therefore, there is a possibility that the characteristics of the second laser light B2 become worse than expected. In addition, in order to maintain the pulse energy Epo of the second laser light B2 at the PO target pulse energy, the charge voltage of the charger 22 needs to be increased. Therefore, there is a possibility that the lifetime of the laser chamber 20 becomes shorter than expected.
(3) The optimum value of the MO target pulse energy may vary depending on the individual difference of the power oscillator PO. For example, when the pulse energy Emo of the first laser light B1 is lower than the optimum value, there is a possibility that the characteristics of the second laser light B2 becomes worse than expected. On the other hand, when the pulse energy Emo of the first laser light B1 is higher than the optimum value, there is a possibility that the lifetime of the laser chamber 10 becomes shorter than expected.

In some embodiments described below, the condition of changing the amplification characteristic of the power oscillator PO is determined. When the condition is satisfied, the pulse energy Emo of the first laser light B1 and the parameter of the second laser light B2 are actually measured to acquire the relationship therebetween, and the MO target pulse energy is set based on the acquired relationship. Accordingly, appropriate MO target pulse energy can be set in accordance with a change in the amplification characteristic of the power oscillator PO.

### 2. Laser System 1a to Set MO Target Pulse Energy as Measuring Pulse Energy Epo of Second Laser Light B2

### 2.1 Configuration

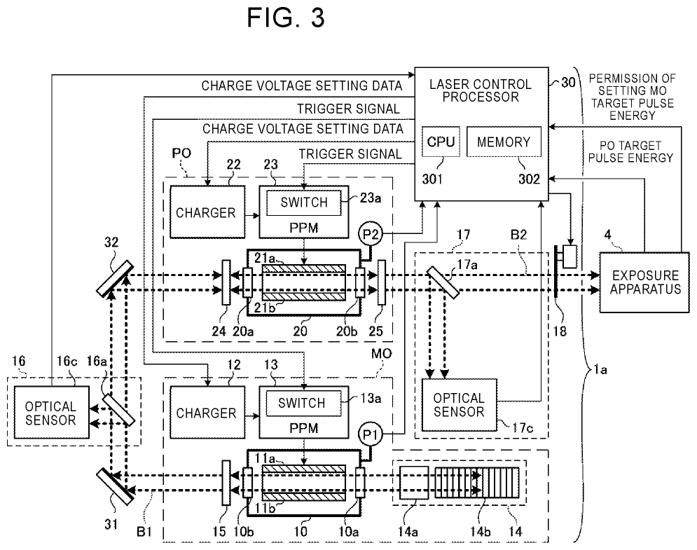

FIG. 3 schematically shows the configuration of a laser system 1a according to a first embodiment. The laser system 1a is different from the comparative example in that the laser control processor 30 receives permission of setting the MO target pulse energy from the exposure apparatus 4 and sets the MO target pulse energy. In other respects, the configuration of the first embodiment is similar to that of the comparative example.

### 2.2 Operation

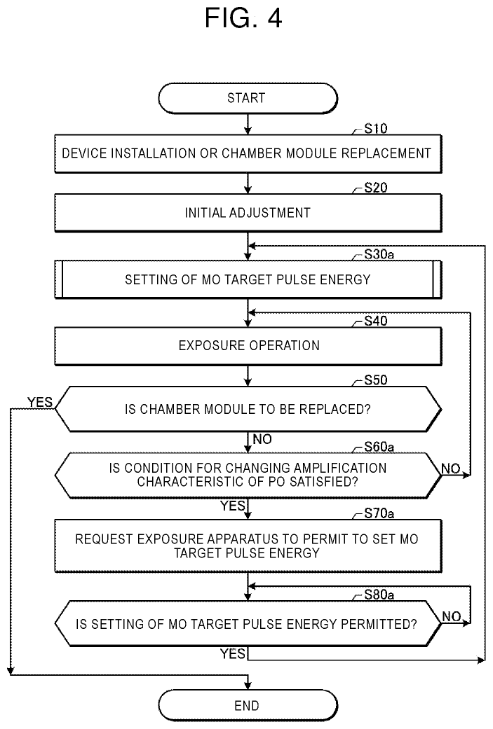

FIG. 4 is a flowchart showing an operation procedure from installation to the end of the of the chamber module lifetime in the first embodiment. S10 and S20 are similar to the corresponding steps in the comparative example.

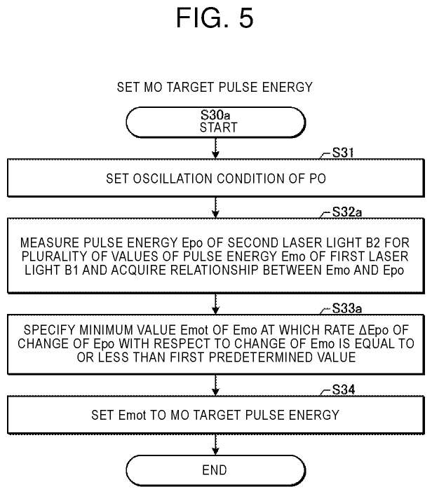

In S30a, the laser control processor 30 sets the MO target pulse energy. Details of this process will be described later with reference to FIGS. 5 to 7. There is a possibility that the process of S30a is performed a plurality of times until the operation procedure of the present flowchart ends, and that a new MO target pulse energy is set each time. In S30a, the laser control processor 30 controls the shutter 18 to be in the second state in order to stop outputting the second laser light B2 to the exposure apparatus 4.

S40 and S50 are similar to the corresponding steps in the comparative example. However, when the laser control processor 30 determines that the chamber module is not to be replaced (S50: NO), processing proceeds to S60a.

In S60a, the laser control processor 30 determines whether or not the condition for changing the amplification characteristic of the power oscillator PO is satisfied. For example, when any of the following (1) to (7) is satisfied, it is determined that the condition is satisfied.
(1) The number of oscillation pulses after setting the MO target pulse energy in S30a has reached a second number of pulses So.
(2) The elapse time after setting the MO target pulse energy in S30a has reached a second elapse time To.
(3) The gas pressure in the laser chamber 20 has been out of a predetermined gas pressure range.
(4) The change in the gas pressure in the laser chamber 20 after setting the MO target pulse energy in S30a has exceeded a predetermined gas pressure change amount ΔP.
(5) The high voltage applied between the discharge electrodes 21a, 21b has been out of a predetermined voltage range.
(6) The change in the high voltage applied between the discharge electrodes 21a, 21b after setting the MO target pulse energy in S30a has exceeded a predetermined voltage change amount ΔV.
(7) Setting data for changing the PO target pulse energy has been received from the exposure apparatus 4.

Here, the second number of pulses So is smaller than the first number of pulses Sm, and is set to, for example, in a range of 0.5×10⁹ pulses or more and 2×10⁹ pulses or less. The second elapse time To is smaller than the first elapse time Tm, and is set to be, for example, in a range of 7 days or more and 15 days or less. The predetermined gas pressure range is, for example, a range of 220 kPa or more and 350 kPa or less. The gas pressure change amount ΔP is set to be, for example, in a range of 50 kPa or more and 150 kPa or less. The predetermined voltage range is, for example, a range of 20 kV or more and 25 kV or less. The voltage change amount ΔV is set to be, for example, in a range of 0.5 kV or more and 1 kV or less. The high voltage applied between the discharge electrodes 21a, 21b may be calculated based on the charge voltage of the charger 22.

When the laser control processor 30 determines that the condition for changing the amplification characteristic of the power oscillator PO is not satisfied (S60a: NO), the exposure operation is continued as returning to S40. When the laser control processor 30 determines that the condition for changing the amplification characteristic of the power oscillator PO is satisfied (S60a: YES), processing proceeds to S70a.

In S70a, the laser control processor 30 requests the exposure apparatus 4 to permit to set the MO target pulse energy. In S80a, the laser control processor 30 determines whether setting the MO target pulse energy is permitted by the exposure apparatus 4. When setting the MO target pulse energy is not permitted (S80a: NO), the laser control processor 30 waits until setting the MO target pulse energy is permitted. When setting the MO target pulse energy is permitted (S80a: YES), the laser control processor 30 sets the MO target pulse energy again as returning to S30a.

### 2.3 Setting Process of MO Target Pulse Energy

FIG. 5 is a flowchart for explaining details of a setting process of the MO target pulse energy in the first embodiment. The processing shown in FIG. 5 corresponds to the subroutine of S30a in FIG. 4.

In S31, the laser control processor 30 sets the oscillation condition of the power oscillator PO. The oscillation condition of the power oscillator PO includes the charge voltage of the charger 22 and the gas pressure in the laser chamber 20. The oscillation condition of the power oscillator PO varies depending on the PO target pulse energy. The oscillation condition of the power oscillator PO may be set based on the PO target pulse energy received from the exposure apparatus 4.

In S32a, the laser control processor 30 sets a plurality of values as the pulse energy Emo of the first laser light B1, and measures the pulse energy Epo of the second laser light B2 for each value. The oscillation condition set in S31 is maintained without being changed until the process of S32a is completed. The laser control processor 30 acquires the relationship between the pulse energy Emo of the first laser light B1 and the pulse energy Epo of the second laser light B2 from the measurement result. The pulse energy Epo of the second laser light B2 is an example of the parameter in the present disclosure.

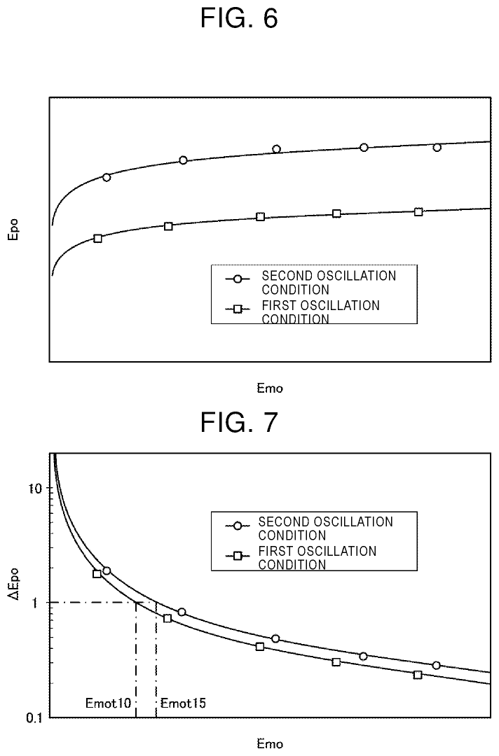

FIG. 6 is a graph showing the measurement result of the relationship between the pulse energy Emo of the first laser light B1 and the pulse energy Epo of the second laser light B2. FIG. 6 shows the measurement result under a first oscillation condition of the power oscillator PO as the PO target pulse energy being 10 mJ, and the measurement result under a second oscillation condition of the power oscillator PO as the PO target pulse energy being 15 mJ.

In S33a of FIG. 5, the laser control processor 30 specifies the minimum value Emot of the pulse energy Emo of the first laser light B1 at which a rate ΔEpo of the change of the pulse energy Epo of the second laser light B2 with respect to the change of the pulse energy Emo of the first laser light B1 is equal to or less than a first predetermined value. The first predetermined value is, for example, 1.

FIG. 7 is a graph showing the relationship between the pulse energy Emo of the first laser light B1 and the change rate ΔEpo of the pulse energy Epo of the second laser light B2. When the pulse energy Epo of the second laser light B2 shown in FIG. 6 is regarded as a function of the pulse energy Emo of the first laser light B1, the change rate ΔEpo shown in FIG. 7 corresponds to the result of differentiating the pulse energy Epo by the pulse energy Emo.

The change rate ΔEpo of the pulse energy Epo of the second laser light B2 is an example of the characteristic of the second laser light B2 in the present disclosure. The change rate ΔEpo is preferably 1, which is the first predetermined value, or less. That is, when the pulse energy Emo of the first laser light B1 is changed by 1 mJ, the change in the pulse energy Epo of the second laser light B2 is preferably equal to or less than 1 mJ. From FIG. 7, by obtaining the pulse energy Emo of the first laser light B1 at which the change rate ΔEpo becomes 1 under the first oscillation condition, the minimum value Emot of the pulse energy Emo at which the characteristic of the second laser light B2 falls within the allowable range can be obtained. The minimum value Emot of the pulse energy Emo at which the characteristic of the second laser light B2 falls within the allowable range under the first oscillation condition is shown as Emot10 in FIG. 7. From FIG. 7, by obtaining the pulse energy Emo of the first laser light B1 at which the change rate ΔEpo becomes 1 under the second oscillation condition, the minimum value Emot of the pulse energy Emo at which the characteristic of the second laser light B2 falls within the allowable range can be obtained. The minimum value Emot of the pulse energy Emo at which the characteristic of the second laser beam B2 falls within the allowable range under the second oscillation condition is shown as Emot15 in FIG. 7. The first predetermined value is not limited to 1, and may be set in a range of 0.5 or more and 2.0 or less.

In S34 of FIG. 5, the laser control processor 30 sets the minimum value Emot to the MO target pulse energy. After S34, the laser control processor 30 ends processing of the present flowchart and returns to processing shown in FIG. 4.

### 2.4 Effect

(1) In the first embodiment, the laser system 1a includes the master oscillator MO that outputs the first laser light B1, and the power oscillator PO that amplifies the first laser light B1 and outputs the second laser light B2. The method of controlling the laser system 1a includes determining a condition under which the amplification characteristic of the power oscillator PO changes, acquiring the relationship between the pulse energy Emo of the first laser light B1 and the parameter of the second laser light B2 when the condition is determined to be satisfied, and setting the MO target pulse energy based on the acquired relationship. According to this, when it is determined that the amplification characteristic of the power oscillator PO changes, the relationship between the pulse energy Emo of the first laser light B1 and the parameter of the second laser light B2 is acquired to set the MO target pulse energy. Therefore, the MO target pulse energy can be set appropriately in accordance with the change in the amplification characteristic of the power oscillator PO.
(2) In the first embodiment, the condition under which the amplification characteristic of the power oscillator PO changes may include that one of the number of oscillation pulses and the elapse time after the MO target pulse energy is previously set has reached the second number of pulses So or the second elapse time To as the corresponding set value. According to this, it is determined that the amplification characteristic of the power oscillator PO may be changed due to the deterioration of the chamber module of the power oscillator PO according to the number of oscillation pulses or the elapse time, and the MO target pulse energy can be set appropriately.
(3) In the first embodiment, the power oscillator PO may be a gas laser device, and the condition under which the amplification characteristic of the power oscillator PO is changed may include that one of the gas pressure and the change in the gas pressure in the power oscillator PO is out of the corresponding set range. According to this, it is determined that the amplification characteristic of the power oscillator PO may be changed by monitoring the gas pressure in the power oscillator PO, and the MO target pulse energy can be set appropriately.
(4) In the first embodiment, the power oscillator PO may be a discharge-excitation-type gas laser device, and the condition under which the amplification characteristic of the power oscillator PO is changed may include that one of the application voltage and the change of the application voltage in the power oscillator PO has been out of the corresponding set range. According to this, it is determined that the amplification characteristic of the power oscillator PO may be changed by monitoring the application voltage in the power oscillator PO, and the MO target pulse energy can be set appropriately.
(5) In the first embodiment, the condition under which the amplification characteristic of the power oscillator PO is changed may include changing the PO target pulse energy. According to this, it is determined that the amplification characteristic of the power oscillator PO may be changed when the PO target pulse energy is changed, and the MO target pulse energy can be set appropriately.
(6) In the first embodiment, the laser system 1a is connected to the exposure apparatus 4, and is configured to output the second laser light B2 to the exposure apparatus 4. In the first embodiment, when it is determined that the condition under which the amplifying characteristic of the power oscillator PO is changed is satisfied, the output of the second laser light B2 to the exposure apparatus 4 is stopped, and the pulse energy Emo of the first laser light B1 and the parameter of the second laser light B2 are measured. Thus, the relationship between the pulse energy Emo of the first laser light B1 and the parameter of the second laser light B2 is acquired. According to this, since the output to the exposure apparatus 4 is stopped, the relationship between the pulse energy Emo of the first laser light B1 and the parameter of the second laser light B2 can be acquired separately from the characteristics of the laser light to be used for the exposure.
(7) In the first embodiment, the MO target pulse energy is set to the minimum value Emot of the pulse energy Emo of the first laser light B1 at which the characteristic of the second laser light B2 falls within the allowable range. According to this, owing to that the minimum value Emot in the range satisfying the condition for acquiring the desired characteristics of the second laser light B2 is set as the MO target pulse energy, the lifetime of the laser chambers 10, 20 can be prevented from being shortened.
(8) In the first embodiment, the parameter of the second laser light B2 is the pulse energy Epo of the second laser light B2. According to this, the MO target pulse energy can be set appropriately based on the relationship between the pulse energy Emo of the first laser light B1 and the pulse energy Epo of the second laser light B2.
(9) In the first embodiment, the MO target pulse energy is set to the minimum value Emot of the pulse energy Emo of the first laser light B1 at which the rate ΔEpo of the change of the pulse energy Epo of the second laser light B2 with respect to the change of the pulse energy Emo of the first laser light B1 is equal to or less than the first predetermined value. According to this, since the MO target pulse energy is set in a range in which the change rate ΔEpo is equal to or less than the first predetermined value, an unintended fluctuation of the pulse energy Epo can be suppressed. In other respects, the first embodiment is similar to the comparative example.

### 3. Laser System 1a Setting MO Target Pulse Energy as Measuring Pulse Energy Variation σEpo of the Second Laser Light B2

### 3.1 Operation

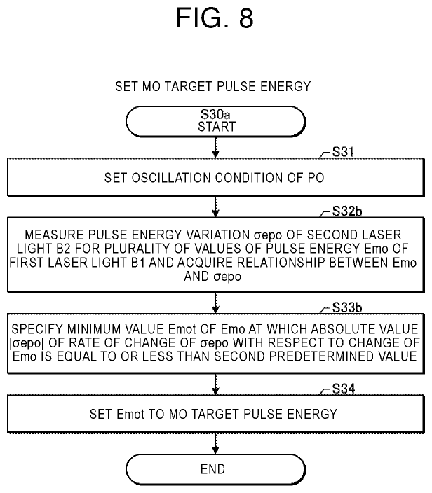

FIG. 8 is a flowchart for explaining details of a setting process of the MO target pulse energy in a second embodiment. The processing shown in FIG. 8 corresponds to the subroutine of S30a in FIG. 4. The configuration and the operation procedure from the installation to the end of the lifetime of the chamber module of the second embodiment are similar to those in the first embodiment.

The process of S31 is similar to that of the first embodiment. In S32b, the laser control processor 30 sets a plurality of values as the pulse energy Emo of the first laser light B1, and measures pulse energy variation σepo of the second laser light B2 for each value. The oscillation condition set in S31 is maintained without being changed until the process of S32b is completed. The laser control processor 30 acquires, from the measurement result, the relationship between the pulse energy Emo of the first laser light B1 and the pulse energy variation σepo of the second laser light B2. The pulse energy variation σepo of the second laser light B2 is an example of the parameter in the present disclosure.

The pulse energy variation σepo is, for example, a variation coefficient and is calculated by the following equation.

σepo=Eposd/Epoavg

When the pulse energy Epo is measured for a plurality of pulses of the second laser light B2 with the pulse energy Emo of the first laser light B1 being a constant value, Eposd is the standard deviation of the pulse energy Epo and Epoavg is the arithmetic mean of the pulse energy Epo.

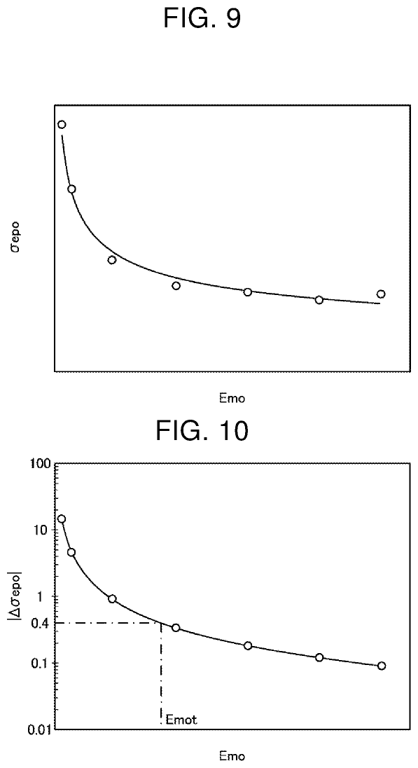

FIG. 9 is a graph showing a measurement result of the relationship between the pulse energy Emo of the first laser light B1 and the pulse energy variation σepo of the second laser light B2. The pulse energy variation σepo may be expressed as a percentage.

In S33b of FIG. 8, the laser control processor 30 specifies the minimum value Emot of the pulse energy Emo of the first laser light B1 at which the absolute value |Δσepo| of the rate of the change of the pulse energy variation σepo of the second laser light B2 with respect to the change of the pulse energy Emo of the first laser light B1 is equal to or less than a second predetermined value. The second predetermined value is, for example, 0.4.

FIG. 10 is a graph showing the relationship between the pulse energy Emo of the first laser light B1 and the absolute value |Δσepo| of the change rate of the pulse energy variation σepo of the second laser light B2. When the pulse energy variation σepo of the second laser light B2 shown in FIG. 9 is regarded as a function of the pulse energy Emo of the first laser light B1, the absolute value |Δσepo| of the change rate shown in FIG. 10 corresponds to the absolute value of the result of differentiating the pulse energy variation σepo by the pulse energy Emo.

The absolute value |Δσepo| of the change rate of the pulse energy variation σepo of the second laser light B2 is an example of the characteristic of the second laser light B2 in the present disclosure. The absolute value |Δσepo| of the change rate is preferably 0.4, which is the second predetermined value, or less. That is, it is preferable that the change in the standard deviation Eposd of the pulse energy Epo of the second laser light B2 when the pulse energy Emo of the first laser light B1 is changed by 1 mJ is 0.4% or less of the arithmetic mean Epoavg of the pulse energy Epo of the second laser light B2. From FIG. 10, by obtaining the pulse energy Emo of the first laser light B1 at which the absolute value |Δσepo| of the change rate is 0.4, the minimum value Emot of the pulse energy Emo at which the characteristic of the second laser light B2 falls within the allowable range can be obtained. The second predetermined value is not limited to 0.4, and may be set in a range of 0.2 or more and 1.5 or less.

The process of S34 of FIG. 8 is similar to that of the first embodiment. After S34, the laser control processor 30 terminates the processing of the present flowchart and returns to processing shown in FIG. 4.

### 3.2 Effect

(10) In the second embodiment, the parameter of the second laser light B2 is the pulse energy variation σepo of the second laser light B2. According to this, the MO target pulse energy can be set appropriately based on the relationship between the pulse energy Emo of the first laser light B1 and the pulse energy variation σepo of the second laser light B2.
(11) In the second embodiment, the MO target pulse energy is set to the minimum value Emot of the pulse energy Emo of the first laser light B1 at which the absolute value |Δσepo| of the rate of the change of the pulse energy variation σepo of the second laser light B2 with respect to the change of the pulse energy Emo of the first laser light B1 is equal to or less than the second predetermined value. According to this, since the MO target pulse energy is set in the range in which the absolute value |Δσepo| of the change rate is equal to or less than the second predetermined value, the characteristic of the second laser light B2 can be within the allowable range. In other respects, the second embodiment is similar to the first embodiment.

### 4. Laser System 1c Setting MO Target Pulse Energy as Measuring Contrast C of Interference Fringes Due to Second Laser Light B2

### 4.1 Configuration

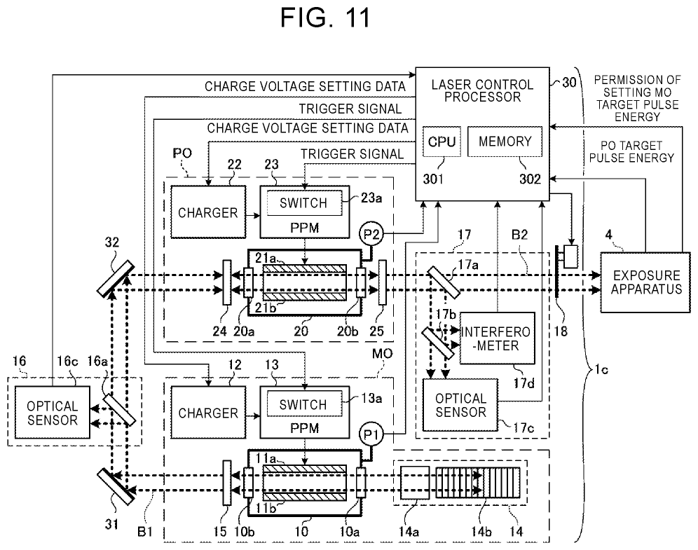

FIG. 11 schematically shows the configuration of a laser system 1c according to a third embodiment. The laser system 1c according to the third embodiment is different from the first and second embodiments in that a beam splitter 17b and an interferometer 17d are added to the PO energy monitor 17.

The beam splitter 17b is arranged on an optical path between the beam splitter 17a and the optical sensor 17c. The interferometer 17d is arranged on the optical path of the light reflected by the beam splitter 17b. The interferometer 17d is a Fabry-Perot interferometer including a diffusion plate, an etalon, a light concentrating lens, and an optical sensor (not shown). The optical sensor of the interferometer 17d may be a line sensor in which a plurality of light receiving elements are arranged in a line manner. The interferometer 17d is configured to measure interference fringes due to the second laser light B2 and transmit the measurement result to the laser control processor 30.

### 4.2 Operation

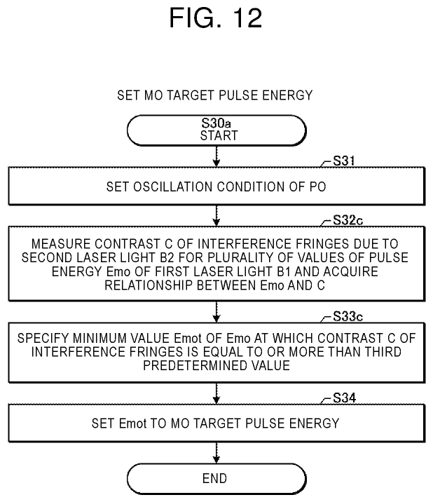

FIG. 12 is a flowchart for explaining details of a setting process of the MO target pulse energy in the third embodiment. The processing shown in FIG. 12 corresponds to the subroutine of S30a in FIG. 4. The operation procedure from the installation to the end of the lifetime of the chamber module in the third embodiment is similar to that in the first embodiment.

The process of S31 is similar to that of the first embodiment. In S32c, the laser control processor 30 sets a plurality of values as the pulse energy Emo of the first laser light B1, and measures the contrast C of the interference fringes due to the second laser light B2 for each value. The oscillation condition set in S31 is maintained without being changed until the process of S32c is completed. The laser control processor 30 acquires, from the measurement result, the relationship between the pulse energy Emo of the first laser light B1 and the contrast C of the interference fringes due to the second laser light B2.

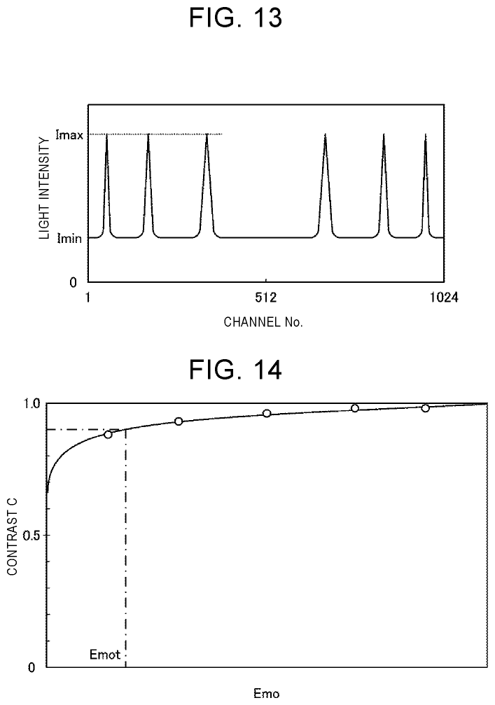

FIG. 13 shows an example of the interference fringes due to the second laser light B2 measured by the interferometer 17d. The horizontal axis of FIG. 13 represents channel numbers, which correspond to numbers of the respective light receiving elements configuring the optical sensor of the interferometer 17d. The contrast C of the interference fringes is calculated, for example, by the following equation.

C=(Imax−Imin)/(Imax+Imin)

Here, Imax is the maximum value of the light intensity in the interference fringes, and Imin is the minimum value of the light intensity in the interference fringes.

In S33c of FIG. 12, the laser control processor 30 specifies the minimum value Emot of the pulse energy Emo of the first laser light B1 at which the contrast C of the interference fringes is equal to or more than a third predetermined value. The third predetermined value is, for example, 0.9.

FIG. 14 is a graph showing the relationship between the pulse energy Emo of the first laser light B1 and the contrast C of the interference fringes.

The contrast C of the interference fringes is an example of the parameter in the present disclosure, and is an example of the characteristic of the second laser light B2 in the present disclosure. The contrast C of the interference fringes is related to the ratio of amplified spontaneous emission included in the second laser light B2. The higher the ratio of the amplified spontaneous emission is, the lower the contrast C of the interference fringes becomes. It is preferable that the ratio of the amplified spontaneous emission is low and the contrast C of the interference fringes is high. The contrast C of the interference fringes is preferably 0.9, which is the third predetermined value, or more. From FIG. 14, by obtaining the pulse energy Emo of the first laser light B1 at which the contrast C of the interference fringes is 0.9, the minimum value Emot of the pulse energy Emo at which the characteristic of the second laser light B2 falls within the allowable range can be obtained. The third predetermined value is not limited to 0.9, and may be set in a range of 0.7 or more and 0.95 or less.

The process of S34 of FIG. 12 is similar to that of the first embodiment. After S34, the laser control processor 30 terminates the processing of the present flowchart and returns to processing shown in FIG. 4.

### 4.3 Other Configuration Example

The parameter of the second laser light B2 measured for a plurality of values of the pulse energy Emo of the first laser light B1 is not limited to the contrast C of the interference fringes. Further, the parameter of the second laser light B2 is not limited to the pulse energy Epo of the second laser light B2 in the first embodiment and the pulse energy variation σepo of the second laser light B2 in the second embodiment. The parameter of the second laser light B2 may include two or more of the pulse energy Epo of the second laser light B2, the pulse energy variation σepo of the second laser light B2, and the contrast C of the interference fringes.

The MO target pulse energy may be set to a maximum value among the minimum values Emot described respectively in the first to third embodiments.

### 4.4 Effect

(12) In the third embodiment, the parameter of the second laser light B2 is a parameter related to a ratio of the amplified spontaneous emission included in the second laser light B2. According to this, the MO target pulse energy can be set appropriately based on the parameter related to the ratio of the amplified spontaneous emission included in the second laser light B2.
(13) In the third embodiment, the parameter related to the ratio of the amplified spontaneous emission included in the second laser light B2 is the contrast C of the interference fringes measured as causing the second laser light B2 to enter the interferometer 17d which is a Fabry-Perot interferometer. According to this, by using the interferometer 17d, it is possible to measure the parameter related to the ratio of the amplified spontaneous emission included in the second laser light B2.
(14) In the third embodiment, the contrast C of the interference fringes is calculated by (Imax−Imin)/(Imax+Imin) based on the maximum value Imax and the minimum value Imin of the light intensity in the interference fringes. According to this, it is possible to appropriately measure the ratio of the amplified spontaneous emission included in the second laser light B2.
(15) In the third embodiment, the MO target pulse energy is set to the minimum value Emot of the pulse energy Emo of the first laser light B1 at which the contrast C of the interference fringes is equal to or more than the third predetermined value. According to this, since the MO target pulse energy is set in a range in which the contrast C of the interference fringes is equal to or more than the third predetermined value, the characteristic of the second laser light B2 can be set within the allowable range.
(16) In the third embodiment, the parameter of the second laser light B2 includes two or more of the pulse energy Epo of the second laser light B2, the pulse energy variation σepo of the second laser light B2, and the contrast C of the interference fringes measured as causing the second laser light B2 to enter the interferometer 17d which is a Fabry-Perot interferometer. The MO target pulse energy is set to the maximum value among the following first to third candidate values.
1. A first candidate value calculated when the parameter includes the pulse energy Epo of the second laser light B2, the first candidate value being the minimum value Emot of the pulse energy Emo of the first laser light B1 at which the rate ΔEpo of the change of the pulse energy Epo of the second laser light B2 with respect to the change of the pulse energy Emo of the first laser light B1 is equal to or less than the first predetermined value.
2. A second candidate value calculated when the parameter includes the pulse energy variation σepo of the second laser light B2, the second candidate value being the minimum value Emot of the pulse energy Emo of the first laser light B1 at which the absolute value |Δσepo| of the rate of the change of the pulse energy variation σepo of the second laser light B2 with respect to the change of the pulse energy Emo of the first laser light B1 is equal to or less than the second predetermined value.
3. A third candidate value calculated when the parameter includes the contrast C of the interference fringes, the third candidate value being the minimum value Emot of the pulse energy Emo of the first laser light B1 at which the contrast C of the interference fringes is equal to or more than the third predetermined value. According to this, the plurality of candidate values are calculated as the minimum value Emot from the viewpoint of extending the lifetime of the laser chamber 10, and the maximum value among the plurality of candidate values is selected, whereby the condition that the characteristic of the second laser light B2 is within the allowable range can be satisfied from a plurality of viewpoints. In other respects, the third embodiment is similar to the first embodiment.

### 5. Laser System 1d in which MO Energy Monitor 16 Also Receives Light Other than Light Output from Master Oscillator MO

### 5.1 Configuration and Operation

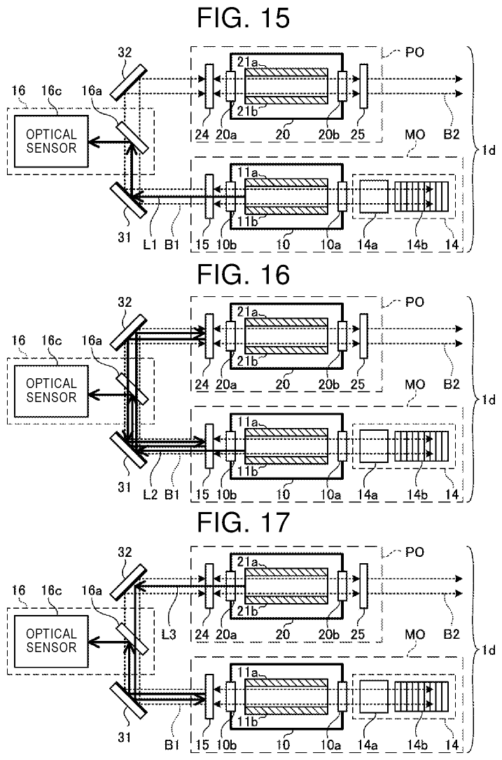

Each of FIGS. 15 to 17 schematically shows an optical path between the master oscillator MO and the power oscillator PO in a laser system 1d according to a fourth embodiment. In FIGS. 15 to 17, the chargers 12, 22, the pulse power modules 13, 23, the PO energy monitor 17, and the like are not shown.

As shown in FIG. 15, the light received by the optical sensor 16c of the MO energy monitor 16 includes light L1 output from the master oscillator MO and entering the MO energy monitor 16. The MO energy monitor 16 measures the pulse energy of the light including the light L1. The MO energy monitor 16 further measures the pulse energy of the light including either or both of light L2 and light L3 described below.

As shown in FIG. 16, the light received by the optical sensor 16c of the MO energy monitor 16 includes the light L2 that is output from the master oscillator MO, reflected by the rear mirror 24, further reflected by the output coupling mirror 15, and entering the MO energy monitor 16. The pulse energy of the light L2 is approximately proportional to the pulse energy of the light L1. The MO energy monitor 16 may measure the pulse energy of light including the light L2.

As shown in FIG. 17, the light received by the optical sensor 16c of the MO energy monitor 16 includes the light L3 that is output from the power oscillator PO through the rear mirror 24, reflected by the output coupling mirror 15, and incident on the MO energy monitor 16. The pulse energy of the light L3 is substantially proportional to the pulse energy Epo of the second laser light B2. The MO energy monitor 16 may measure the pulse energy of light including the light L3.

In order to accurately calculate the pulse energy of the light L1 output from the master oscillator MO, it is conceivable to perform correction calculation of excluding the pulse energy of the light L2 and the pulse energy of the light L3 from the pulse energy measured by the MO energy monitor 16. In order to perform the correction operation, for example, a shutter (not shown) may be provided between the MO energy monitor 16 and the power oscillator PO to separately measure the characteristic data, and a correction factor may be calculated from the measurement result.

However, in the present disclosure, a process (S30a) of setting the MO target pulse energy based on the measurement result of the pulse energy of the light including either or both of the light L2 and the light L3, and a process (S40) of controlling the pulse energy of the light including either or both of the light L2 and the light L3 to approach the MO target pulse energy are performed. According to this, since either or both of the light L2 and the light L3 are taken into consideration in both of the process (S30a) of setting the MO target pulse energy and the process (S40) of controlling the pulse energy, there is no significant problem in the control of the present disclosure.

According to the fourth embodiment, it is possible to obtain the desirable characteristic of the second laser light B2 by controlling the pulse energy Emo of the first laser light B1 even without performing the correction calculation for excluding the pulse energy of the light L2 and the light L3

The operation sequence from the installation to the end of the lifetime of the chamber module in the fourth embodiment and the setting process of the MO target pulse energy may be similar to those in any of the first to third embodiments. However, in S60a (see FIG. 4), at least one of the following conditions (8) to (11) may be added as a condition under which the amplification characteristic of the power oscillator PO changes.
(8) The gas pressure in the laser chamber 10 has been out of the predetermined gas pressure range.
(9) The change in the gas pressure in the laser chamber 10 after setting the MO target pulse energy in S30a has exceeded the predetermined gas pressure change amount ΔP.
(10) The high voltage applied between the discharge electrodes 11a, 11b has been out of the predetermined voltage range.
(11) The change in the high voltage applied between the discharge electrodes 11a, 11b after setting the MO target pulse energy in S30a has exceeded the predetermined voltage change ΔV.

The predetermined gas pressure range, the gas pressure change amount ΔP, the predetermined voltage range, and the voltage change amount ΔV may be similar to those described in the first embodiment. The reason why the change in the amplification characteristic of the power oscillator PO can be determined based on the conditions of the gas pressure in the laser chamber 10 or the high voltage applied between the discharge electrodes 11a, 11b shown in (8) to (11) is as follows.

When the amplification characteristic of the power oscillator PO changes, the pulse energy of the light L3 changes. For example, the pulse energy of the light L3 may increase. In this case, the laser control processor 30 may lower the pulse energy of the light L1 in an attempt to maintain the pulse energy Emo measured by the MO energy monitor 16 at the MO target pulse energy. That is, the high voltage applied between the discharge electrodes 11a, 11b may be lowered, or the gas pressure in the laser chamber 10 may be lowered. As described above, since the gas pressure in the laser chamber 10 or the high voltage applied between the discharge electrodes 11a, 11b may change due to the change in the amplification characteristic of the power oscillator PO, the determination according to the conditions (8) to (11) can be performed.

When the high voltage applied between the discharge electrodes 11a, 11b becomes low or the gas pressure in the laser chamber 10 becomes low, the pulse energy of the light L3 is likely to be high. This is because the high voltage applied between the discharge electrodes 11a, 11b or the gas pressure in the laser chamber 10 normally increases with the deterioration of the chamber unit of the master oscillator MO, and the opposite event indicates a situation different from the normal situation. Therefore, more accurate determination can be performed by adding the conditions (8) to (11) than by using only the conditions (1) to (7) described with reference to FIG. 4.

### 5.2 Effect

(17) In the fourth embodiment, the laser system 1d includes the MO energy monitor 16 arranged on the optical path of the first laser light B1 between the master oscillator MO and the power oscillator PO. The MO energy monitor 16 measures the pulse energy of the light including the light L1 output from the master oscillator MO and entering the MO energy monitor 16, and measures the pulse energy of the light further including any of the light L2 and the light L3 described below.
1. The light L2 that is output from the master oscillator MO, reflected by the rear mirror 24 included in the power oscillator PO, further reflected by the output coupling mirror 15 included in the master oscillator MO, and incident on the MO energy monitor 16.
2. The light L3 that is output from the power oscillator PO through the rear mirror 24, reflected by the output coupling mirror 15, and entering the MO energy monitor 16.

According to this, the pulse energy Emo of the first laser light B1 can be controlled to a desired value even without performing the correction calculation for excluding the pulse energy of the light L2 and the light L3.
(18) In the fourth embodiment, the master oscillator MO may be a discharge-excitation-type gas laser device, and the condition under which the amplification characteristic of the power oscillator PO is changed may include that any of the gas pressure, the change in the gas pressure, the application voltage in the master oscillator MO, and the change in the application voltage has been out of the corresponding set range. According to this, it is possible to determine that the amplification characteristic of the power oscillator PO may be changed by monitoring the gas pressure or the application voltage in the master oscillator MO, and to the MO target pulse energy can be set appropriately. In other respects, the fourth embodiment is similar to the first to third embodiments.

### 6. Laser System 1e Including Ring Resonator

### 6.1 Configuration

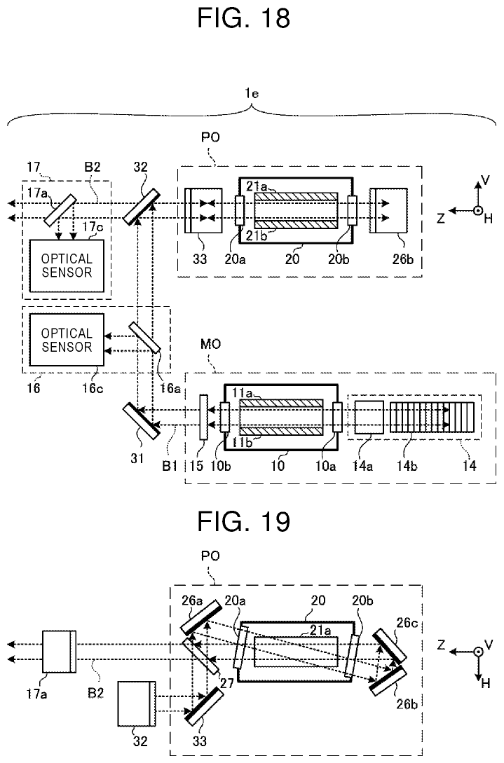

FIG. 18 schematically shows the configuration of a laser system 1e according to a fifth embodiment. FIG. 19 shows the power oscillator PO shown in FIG. 18 as viewed from a direction different from that of FIG. 18. In FIGS. 18 and 19, the output direction of the second laser light B2 output from the power oscillator PO is defined as a Z direction, and the discharge direction between the discharge electrodes 21a, 21b is defined as a V direction. The Z direction and the V direction are perpendicular to each other, and the direction perpendicular to both of them is defined as an H direction.

In the first to fourth embodiments, the power oscillator PO is configured using a Fabry-Perot type optical resonator, whereas in the fifth embodiment, the power oscillator PO is configured using a ring resonator.

The laser system 1e according to the fifth embodiment includes high reflection mirrors 26a to 26c, an output coupling mirror 27, and a high reflection mirror 33 instead of the rear mirror 24 and the output coupling mirror 25 in the laser system 1a according to the first embodiment. In FIGS. 18 and 19, the chargers 12, 22, the pulse power modules 13, 23, and the like are not shown.

The output coupling mirror 27 is made of a material that transmits the first laser light B1, and one surface thereof is coated with a partial reflection film. The output coupling mirror 27 and the high reflection mirror 26a are arranged outside of the laser chamber 20 and in the vicinity of the window 20a. The high reflection mirrors 26b, 26c are arranged outside the laser chamber 20 and in the vicinity of the window 20b. In the discharge space between the discharge electrodes 21a, 21b, the optical path from the high reflection mirror 26a to the high reflection mirror 26b intersects with the optical path from the high reflection mirror 26c to the output coupling mirror 27.

The PO energy monitor 17 is arranged on the optical path of the second laser light B2 output from the power oscillator PO.

### 6.2 Operation

The first laser light B1 output from the master oscillator MO is reflected by the high reflection mirrors 31, 32, 33 in this order, and incident on the output coupling mirror 27 from the outside of the resonator of the power oscillator PO substantially in the −H direction. The first laser light B1 that enters the resonator through the output coupling mirror 27 is reflected by the high reflection mirrors 26a, 26b, 26c in this order, amplified when passing through the discharge space, and incident on the output coupling mirror 27 in the Z direction from the inside of the resonator.

A part of the light incident on the output coupling mirror 27 in the Z direction is reflected substantially in the −H direction, reflected again by the high reflection mirrors 26a, 26b, 26c, and amplified. Another part of the light incident on the output coupling mirror 27 in the Z direction is transmitted and output as the second laser light B2.

In the fifth embodiment, the setting process of the MO target pulse energy may be similar to any of those in the first to third embodiments.

### 6.3 Effect

The fifth embodiment has operation similar to that of the first to third embodiments. In other respects, the fifth embodiment is similar to the first to third embodiments.

### 7. Others

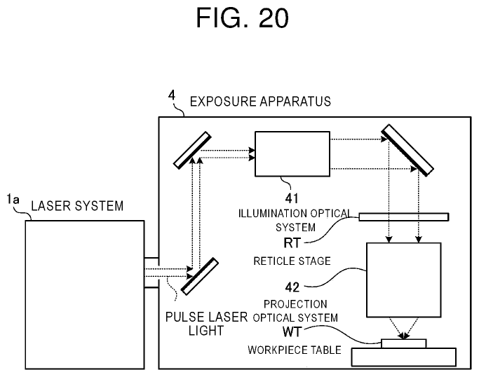

FIG. 20 schematically shows the configuration of the exposure apparatus 4 connected to the laser system 1a. The laser system 1a generates pulse laser light and outputs the pulse laser light to the exposure apparatus 4. In FIG. 20, the exposure apparatus 4 includes an illumination optical system 41 and a projection optical system 42. The illumination optical system 41 illuminates a reticle pattern of a reticle (not shown) arranged on a reticle stage RT with the pulse laser light incident from the laser system 1a. The projection optical system 42 causes the pulse laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 4 synchronously translates the reticle stage RT and the workpiece table WT to expose the workpiece to the pulse laser light reflecting the reticle pattern. After the reticle pattern is transferred onto the semiconductor wafer by the exposure process described above, an electronic device can be manufactured through a plurality of processes. Instead of the laser system 1a, any of the laser systems 1c, 1d, le may be used.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A control method of a laser system which comprises an oscillation stage laser configured to output first laser light, and an amplification stage laser configured to amplify the first laser light and output second laser light, the control method comprising:
determining a condition under which an amplification characteristic of the amplification stage laser changes;
acquiring relationship between pulse energy of the first laser light and a parameter of the second laser light when the condition is determined to be satisfied; and
setting target pulse energy of the first laser light based on the relationship.

2. The control method according to claim 1,
wherein the condition includes that one of a number of oscillation pulses and an elapse time after the target pulse energy of the first laser light is previously set reaches a corresponding set value.

3. The control method according to claim 1,
wherein the amplification stage laser is a gas laser device, and
the condition includes that one of a gas pressure and a change in the gas pressure in the amplification stage laser is out of a corresponding set range.

4. The control method according to claim 1,
wherein the amplification stage laser is a discharge-excitation-type gas laser device, and
the condition includes that one of an application voltage and a change in the application voltage in the amplification stage laser is out of a corresponding set range.

5. The control method according to claim 1,
wherein the condition includes changing target pulse energy of the second laser light.

6. The control method according to claim 1,
wherein the laser system is connected to an exposure apparatus, and is configured to output the second laser light to the exposure apparatus, and
the relation is acquired, when the condition is determined to be satisfied, by measuring the pulse energy of the first laser light and the parameter of the second laser light while outputting the second laser light to the exposure apparatus is stopped.

7. The control method according to claim 1,
wherein the target pulse energy of the first laser light is set to a minimum value of the pulse energy of the first laser light at which the characteristic of the second laser light falls within an allowable range,

8. The control method according to claim 1,
wherein the parameter is pulse energy of the second laser light.

9. The control method according to claim 8,
wherein the target pulse energy of the first laser light is set to a minimum value of the pulse energy of the first laser light at which a rate of a change in the pulse energy of the second laser light with respect to a change in the pulse energy of the first laser light is equal to or less than a first predetermined value.

10. The control method according to claim 1,
wherein the parameter is pulse energy variation of the second laser light.

11. The control method according to claim 10,
wherein the target pulse energy of the first laser light is set to a minimum value of the pulse energy of the first laser light at which an absolute value of a rate of a change in the pulse energy variation of the second laser light with respect to a change in the pulse energy of the first laser light is equal to or less than a second predetermined value.

12. The control method according to claim 1,
wherein the parameter is a parameter related to a ratio of the amplified spontaneous emission included in the second laser light.

13. The control method according to claim 12,
wherein the parameter related to the ratio is a contrast of interference fringes measured as causing the second laser light to enter a Fabry-Perot interferometer.

14. The control method according to claim 13,
wherein the contrast is calculated by (Imax−Imin)/(Imax+Imin) based on a maximum value Imax and a minimum value Imin of the light intensity in the interference fringes.

15. The control method according to claim 13,
wherein the target pulse energy of the first laser light is set to a minimum value of the pulse energy of the first laser light at which the contrast is equal to or more than a third predetermined value.

16. The control method according to claim 1,
wherein the parameter includes two or more of pulse energy of the second laser light, pulse energy variation of the second laser light, and a contrast of the interference fringes measured as causing the second laser light to enter a Fabry-Perot interferometer, and
the target pulse energy of the first laser light is set to a maximum value among:
a first candidate value calculated when the parameter includes the pulse energy of the second laser light, the first candidate value being a minimum value of the pulse energy of the first laser light at which a rate of a change of the pulse energy of the second laser light with respect to a change of the pulse energy of the first laser light is equal to or less than a first predetermined value,
a second candidate value calculated when the parameter includes the pulse energy variation of the second laser light, the second candidate value being a minimum value of the pulse energy of the first laser light at which an absolute value of a rate of a change of the pulse energy variation of the second laser light with respect to the change of the pulse energy of the first laser light is equal to or less than a second predetermined value, and
a third candidate value calculated when the parameter includes the contrast, the third candidate value being a minimum value of the pulse energy of the first laser light at which the contrast is equal to or more than a third predetermined value.

17. The control method according to claim 1,
wherein the laser system includes an energy monitor arranged on an optical path of the first laser light between the oscillation stage laser and the amplification stage laser,
the energy monitor measures pulse energy of light including light output from the oscillation stage laser and entering the energy monitor, and further including any of light output from the oscillation stage laser, reflected by a first partial reflection mirror included in the amplification stage laser, further reflected by a second partial reflection mirror included in the oscillation stage laser, and entering the energy monitor, and light output from the amplification stage laser via the first partial reflection mirror, reflected by the second partial reflection mirror, and entering the energy monitor.

18. The control method according to claim 1,
wherein the oscillation stage laser is a discharge-excitation-type gas laser device, and
the condition includes that any of a gas pressure in the oscillation stage laser, a change in the gas pressure, an application voltage in the oscillation stage laser, and a change in the application voltage is out of a corresponding set range.

19. A laser system comprising:
an oscillation stage laser configured to output first laser light;
an amplification stage laser configured to amplify the first laser light and output second laser light; and
a processor configured to determine a condition under which an amplification characteristic of the amplification stage laser changes, acquire relationship between pulse energy of the first laser light and a parameter of the second laser light when the condition is determined to be satisfied, and set target pulse energy of the first laser light based on the relationship.

20. An electronic device manufacturing method, comprising:
generating laser light using a laser system;
outputting the laser light to an exposure apparatus; and
exposing a photosensitive substrate to the laser light in the exposure apparatus to manufacture an electronic device,
the laser system including:
an oscillation stage laser configured to output first laser light;
an amplification stage laser configured to amplify the first laser light and output second laser light; and
a processor configured to determine a condition under which an amplification characteristic of the amplification stage laser changes, acquire relationship between pulse energy of the first laser light and a parameter of the second laser light when the condition is determined to be satisfied, and set target pulse energy of the first laser light based on the relationship.
